(19) United States
(12) Patent Application Publication
(10) Pub. No.: US 2024/0128133 A1
(43) Pub. Date: Apr. 18, 2024

(54) VERTICAL SEMICONDUCTOR COMPONENT ON THE BASIS OF GALLIUM NITRIDE WITH A FRONT-SIDE MEASURING ELECTRODE

(71) Applicant: Robert Bosch GmbH, Stuttgart (DE)

(72) Inventors: Jens Baringhaus, Sindelfingen (DE); Klaus Heyers, Reutlingen (DE)

(21) Appl. No.: 18/486,367

(22) Filed: Oct. 13, 2023

(30) Foreign Application Priority Data
Oct. 14, 2022 (DE) 10 2022 210 851.5

(51) Int. Cl. H01L 21/66; H01L 29/20; H01L 29/66; H01L 29/778

(52) U.S. Cl. CPC H01L 22/32; H01L 22/10; H01L 29/2003; H01L 29/66462; H01L 29/7788

(57) ABSTRACT

A vertical semiconductor component, in particular transistor, with a drift layer and/or an active layer on the basis of gallium nitride (GaN), and at least two, preferably three, electrodes. At least one measuring electrode is formed at a lower vertical level than the at least one other electrode and is designed to be contactable from vertically above.

### FIELD

The present invention relates to a semiconductor component in a vertical design on the basis of gallium, in particular on the basis of gallium nitride. Furthermore, the present invention relates to a composite of semiconductor components on the basis of gallium nitride, to a method for producing corresponding semiconductor components, and to composites of semiconductor components.

### BACKGROUND INFORMATION

Vertical semiconductor components are generally conventional. In them, the final connection electrodes are distributed to two vertically opposite sides of the semiconductor component, in particular the corresponding layer structure, so that space-saving contacting is enabled. Moreover, vertical semiconductor components enable a vertical current flow between said electrodes arranged vertically above one another.

Semiconductor components, in particular transistors, on the basis of gallium nitride (GaN) are also described in the related art. These semiconductor components have a particularly advantageously low on-resistance (electrical resistance in the conductive state) with simultaneously high breakdown voltages or breakdown field strengths in comparison to semiconductor components on the basis of silicon or silicon carbide. Semiconductor components on the basis of gallium nitride are disadvantageous in that the material is relatively expensive and must be used extremely sparingly in order to realize corresponding semiconductor components economically.

Against this background, there are already approaches in the related art to heteroepitaxially form a semiconductor component on the basis of gallium nitride, in particular with a drift layer and/or an active layer on the basis of gallium nitride, on a foreign substrate, which neither comprises nor consists of gallium nitride. A corresponding semiconductor structure as well as a corresponding method are described in German Patent Application No. DE 10 2020 210 937 A1.

In such methods, a highly doped contact semiconductor layer is applied onto the foreign substrate, optionally after applying one or more intermediate layers to compensate for the lattice mismatch between the following nitride semiconductor layers and the foreign substrate, and later, in particular after the removal of the foreign substrate and/or the intermediate layer, serves as a rear support or bottom support for an electrode, in particular a drain electrode. In order to remove the foreign substrate, in particular in order to ensure a minimum mechanical stability, it may be necessary to apply or fasten at least temporarily a carrier material to the end of the semiconductor layer structure opposite to the foreign substrate. However, this carrier material then regularly covers the electrodes of the vertical electrode arrangement, in particular the source electrode and/or the gate electrode, formed and arranged on the vertically upper end of the semiconductor layer structure, also referred to as the front side in the technical jargon.

A characterization of the semiconductor components during the production process is thereby made more difficult or impossible since vertical contacting of the correspondingly opposite electrodes is not possible at any point in time of the process since the respective electrode or a contactable layer, such as the contact semiconductor layer, is/are covered by other materials at least on one side or at one vertical end of the semiconductor layer structure and/or the respective electrode is/are not yet formed.

### SUMMARY

The vertical semiconductor component according to the present invention with a drift layer and/or an active layer on the basis of gallium nitride may have the advantage that even during the production process, in particular prior to removal of a foreign substrate and/or any intermediate layers, at least indirect vertical electrical contacting and thus characterization of the semiconductor component is made possible, in particular in a state in which the semiconductor component has a necessary mechanical stability to be automatically characterized by means of appropriate devices.

In light of the above explanations, in the semiconductor component, in particular transistor, according to the present invention with a drift layer and/or an active layer on the basis of gallium nitride and at least two, preferably three, electrodes, it is therefore provided according to an example embodiment of the present invention that at least one measuring electrode is formed at a lower vertical level than the at least one other electrode and is designed to be contactable from vertically above. This enables electrical contacting of the electrodes, including the measuring electrode, preferably overall, from vertically above, wherein, however, the vertical semiconductor component can be measured, in particular characterized, by the vertically lower measuring electrode, without any foreign substrates, intermediate layers or other structures for minimizing the use of gallium nitride, in vertically lower regions having to be removed from below and the mechanical stability having to be compromised accordingly.

A measuring electrode is to be deemed to be contactable from vertically above if no further layers of the semiconductor layer structure are arranged above the measuring electrode or vertically higher layers of the semiconductor layer structure are correspondingly removed. In other words, although a vertically lower measuring electrode that is contactable from vertically above is set back vertically downward in comparison to the vicinity of the semiconductor layer structure, it simultaneously forms the vertically uppermost layer or material layer of the semiconductor component in the region in which it is formed.

With the vertical semiconductor component according to an example embodiment of the present invention, not only the measuring electrode but also a further, vertically higher electrode, for example a source electrode and/or a gate electrode, which forms the vertically upper termination of the layer structure in its respective region of the semiconductor layer structure, can be contacted from above or from the front side and a characterization of the vertical semiconductor component can take place. The measuring electrode can thus serve as a temporary drain electrode or as a transition drain electrode, which is provided, formed and optionally retained for the purpose of characterizing the semiconductor component, in particular at a point in time when, in a region in which a final drain electrode is formed, another layer structure, for example, a foreign substrate and/or an intermediate layer is still arranged and prevents access and/or contact, in particular to/with a contact semiconductor layer, from below.

Advantageous developments of the semiconductor component according to the present invention are disclosed herein.

According to the first advantageous embodiment of the present invention, the measuring electrode can be formed on a contact semiconductor layer. For example, the contact semiconductor layer can comprise or be formed from an n-conductive gallium nitride layer. The contact semiconductor layer can be that layer on which a final electrode, in particular drain electrode, is formed, in particular deposited, preferably at an opposite end or on an opposite side in relation to the arrangement of the measuring electrode.

The measuring electrode can thus at least temporarily form or fulfill the same function as a later electrode, in particular drain electrode, and can therefore also be suitable for characterizing the semiconductor component or a precursor of the corresponding semiconductor component.

In a further, advantageous design of the present invention, it can be provided that the vertical semiconductor component or a corresponding precursor comprises a foreign substrate that does not consist of gallium nitride and preferably does not comprise gallium nitride. As already indicated above, such foreign substrates enable formation of gallium nitride semiconductor components with a minimum amount of gallium nitride used.

In a further, likewise advantageous design of the present invention, it can be provided that an intermediate layer for compensating for the lattice mismatch between a foreign substrate and the contact semiconductor layer and/or the drift layer is realized. Such intermediate layers can be required or at least advantageous for the heteroepitaxial growth of gallium nitride layers on a foreign substrate. This layer or these layers are also referred to as buffer layers or engineered layers.

In a further, likewise preferred embodiment of the semiconductor component of the present invention, it can be provided that the measuring electrode extends over a portion of a width and of a length of the semiconductor component and is arranged in an edge region, preferably a corner region of the semiconductor component. The length and width are to refer to dimensions parallel to a layer extension plane or substrate plane. The edge region or corner region of the semiconductor component is also to refer to a region in the plane or to a plane parallel to the substrate plane. This enables a particularly space-saving realization of the measuring electrode, which does not affect or only insignificantly affects the rest of the structure, in particular the formation of the vertically upper electrodes, preferably gate and source electrodes, and enables a maximum active surface of the semiconductor component.

The present invention also includes a composite of semiconductor components with a plurality of semiconductor components according to one of the above-described embodiments which are arranged next to one another in a longitudinal direction and/or a width direction and in which the measuring electrode is formed in a transition region of two semiconductor components, preferably in a sawing region for separating the semiconductor components. Usually, a plurality of semiconductor components arranged in the shape of a matrix are formed or constructed together on a substrate or wafer. Only at a relatively late point in time of the production process does separation of the individual semiconductor components then take place by separating, in particular sawing, along separation lines in the transition region between individual semiconductor components in the longitudinal direction and in the width direction. In the particularly preferred design of the measuring electrode according to the present invention, in said transition regions, the use of the measuring electrode to characterize the individual semiconductor components can be made possible without the measuring electrode causing area consumption of the final semiconductor component or the active surface thereof, since the measuring electrode is/are arranged entirely or at least largely in the transition regions that will be removed or lost anyway during the separation, in particular sawing, of the semiconductor components.

In an advantageous embodiment of the present invention, it can be provided that the composite of semiconductor components comprises a measuring electrode that is formed circumferentially around a semiconductor component, preferably in transition regions. As a result, the measuring electrode can be deposited or produced in a relatively non-specific and thus particularly simple manner, and contacting can also take place without any problems, in particular without great precision requirements.

In a particularly preferred design of the composite of semiconductor components of the present invention, it can be provided that a single measuring electrode is electrically conductively connected to at least two semiconductor components, in particular semiconductor components arranged next to one another. Since all semiconductor components can be connected to one another at the wafer level via the contact semiconductor layer, it can be made possible by means of a single measuring electrode to contact and/or characterize two or more semiconductor components. Accordingly, the measuring electrode can advantageously be arranged or formed in the transition region between two semiconductor components and be used for measuring or characterizing the two adjacent, and/or further, semiconductor components.

The present invention also includes a method for producing a vertical semiconductor component, in particular a transistor, with at least two, preferably three, electrodes and a drift layer and/or an active layer on the basis of gallium nitride. According to an example embodiment of the present invention, the method includes the following method steps:
forming a semiconductor layer structure comprising at least the drift layer, the active layer, at least one electrode and a vertically lower contact semiconductor layer on a foreign substrate;
ablating the semiconductor layer structure up to the contact semiconductor layer in a portion of the surface in which the semiconductor layer structure has been formed;
forming a vertically lower measuring electrode on the contact semiconductor layer exposed by the ablation.

As a result of this method, which uses generally conventional methods and techniques of semiconductor technology with regard to the layer growth, the layer structuring and the possible influence and processing of formed, in particular grown-on, layers, and particularly as a result of the subsequent, partial ablation or ablation in regions of the semiconductor layer structure up to the contact semiconductor layer, and formation of the measuring electrode on the contact semiconductor layer, the measuring electrode can be contacted from vertically above and simultaneously enables, in an intermediate stage, for example while a foreign substrate and/or at least one intermediate layer is still arranged vertically below the contact semiconductor layer, contacting, preferably indirect or deflected vertical contacting and thus characterization of the semiconductor component.

In an advantageous embodiment of the method of the present invention, it can be provided that, preferably after a test or characterization method using the at least one electrode and the measuring electrode, a carrier material is fastened vertically onto the top of the semiconductor structure and covers the at least one electrode and/or makes it inaccessible. The carrier material can be the basis for removing the foreign substrate and for forming a final vertical semiconductor structure with an electrode, in particular drain electrode, accordingly vertically at the bottom. However, in this case, the measuring electrode provided according to the present invention enables, in a particularly advantageous manner, a characterization or a characterization method before the carrier material is applied or connected and also before the foreign substrate is removed.

As already indicated, in a further, particularly advantageous embodiment of the method of the present invention, it can be provided that the foreign substrate, preferably together with an intermediate layer for compensating for the lattice mismatch between the foreign substrate and the contact semiconductor layer, is removed so that the contact semiconductor layer is exposed, in particular on an opposite side, for the attachment or formation of the measuring electrode. Either a surface-related, partial or complete removal can be provided.

In a further, particularly preferred design of the method of the present invention, it can be provided that, in particular after the removal of the foreign substrate and/or any intermediate layers, an electrode, preferably a drain electrode, is formed, in particular deposited, on the exposed contact semiconductor layer. This ultimately realizes a true, vertical semiconductor component.

Further advantages, features and details of the present invention result from the following description of preferred example embodiments of the present invention and on the basis of the figures.

### BRIEF DESCRIPTION OF THE DRAWINGS

FIG. 1 shows a section through a vertical gallium nitride transistor according to an example embodiment of the present invention.

FIG. 2 shows a schematic plan view of a semiconductor component according to the present invention according to a first example embodiment of the present invention.

FIG. 3 shows a schematic plan view of a section of a composite according to the present invention of semiconductor components according to a second example embodiment of the present invention.

FIG. 4 shows a schematic plan view of a composite of semiconductor components according to a third example embodiment of the present invention.

### DETAILED DESCRIPTION OF EXAMPLE EMBODIMENTS

The same elements or elements having the same function are provided with the same reference signs in the figures.

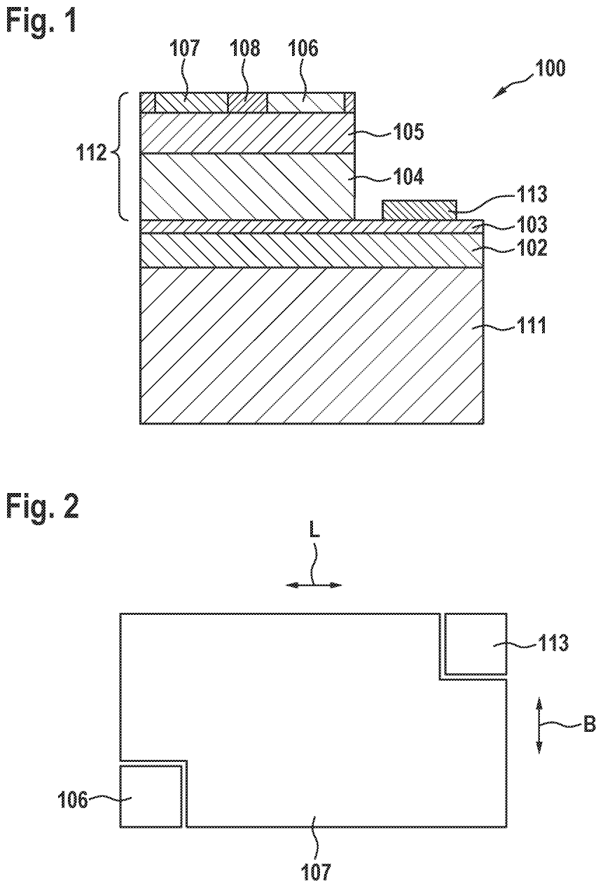

FIG. 1 shows a vertical or quasi-vertical semiconductor component according to the present invention, in particular a transistor 100 according to the present invention. To a foreign substrate 111 is applied an electrically non-conductive intermediate layer 102 for compensating for the lattice mismatch between subsequently applied gallium nitride semiconductor layers and the foreign substrate. Arranged on the intermediate layer 102, in turn, is a highly doped, n-conductive contact semiconductor layer 103 which in turn forms the bottom support for a low-doped, n-conductive drift layer 104 arranged vertically thereabove. In the drift layer 104, an active layer 105 is formed, in particular structured and/or deposited, by the machining steps specific to the respective semiconductor component. The drift layer 104 and the active layer 105 are accordingly both based on gallium nitride, as is the contact semiconductor layer 103.

On the active layer 105, two electrodes are formed as gate electrode 106 and source electrode 107, which are separated from one another by an insulation layer 108. In a particular region of the transistor 100, the semiconductor layer structure 112 up to the contact semiconductor layer 103 can be removed according to the present invention from vertically above or from the front side in order to form the measuring electrode 113 thereon. In FIG. 1, it can be seen that the measuring electrode 113 is located on a lower vertical level than the electrodes 106, 107 and can be contacted from vertical above so that a vertical current flow and thus also a characterization of the transistor 100 is possible, even if, in quasi-vertical contacting, the measuring electrode is contacted from vertically above and is not contacted, as conventionally in a vertical semiconductor component, from vertically below or from the opposite side by the electrodes 106, 107. This design enables in a significant and advantageous manner of the present invention that even with the foreign substrate 111 and the intermediate layer 102, contacting of the transistor 100 is possible and characterization or measurement can take place.

In subsequent method steps for forming the final semiconductor component, in particular transistor 100, it can be provided that a carrier material is arranged on or fastened onto the electrodes 106, 107 and the insulation 108, and that, instead, the layers of the foreign substrate 111 and of the intermediate layer 102 are removed completely or partially (in relation to the surface) in order to form a final electrode, in particular drain electrode 106, opposite the measuring electrode 113 on the contact semiconductor layer 103.

In FIG. 2, in a plan view which is substantially perpendicular to the sectional view of FIG. 1, the arrangement and design of the measuring electrode 113 is again shown. In this representation, it cannot be seen directly that the measuring electrode 113 is designed according to the embodiment of FIG. 1 to be vertically lower or set back. It is however clear that the measuring electrode 113 extends over a portion of the length L and of the width B of the semiconductor component and is arranged in an edge region, in particular a corner region of the semiconductor component. The vertically higher gate electrode 106 can likewise be arranged in a corresponding edge or corner region and extend over a portion of the length L and of the width B. The remainder of the surface of the semiconductor element can preferably be occupied by the source electrode 107 and the corresponding insulation 108 not shown in FIG. 2.

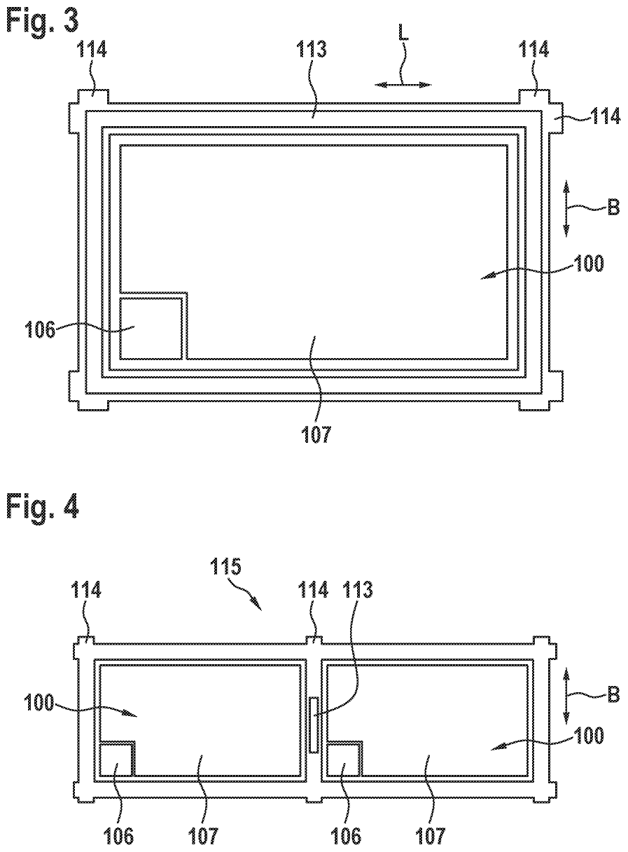

FIG. 3 shows an alternative embodiment of a semiconductor component according to the present invention as well as a composite according to the present invention of semiconductor components, wherein semiconductor components of the composite formed adjacent in the longitudinal direction L and in the width direction B are not shown in detail. However, transition regions 114 can be seen in the longitudinal direction L and in the width direction B, which transition regions can be used to separate, in particular saw apart, the individual semiconductor components, in particular transistors 100. In the embodiment of FIG. 3, the measuring electrode 113 is formed in the transition region 114, in particular circumferentially around the transistor 100 in the transition regions 114. The formation of the measuring electrode 113 can thus be performed without wasting the active surface. In a later separation of the semiconductor components, in particular transistors 100, a majority of the measuring electrode 113, or even the entire measuring electrode 113, can then be removed.

In an alternative embodiment shown in FIG. 4, the measuring electrode 113 is likewise formed in a transition region 114 in the width direction B in a composite 115 of semiconductor components, in which composite, by way of example, two semiconductor elements, in particular transistors 100, arranged next to one another are shown. In the example of FIG. 4, the measuring electrode 113 is formed only in sections or regions in the transition region 114. Furthermore, a single measuring electrode 113 is realized for several, in particular at least two, semiconductor components together in that, as a result of its arrangement on the contact semiconductor layer 103, the measuring electrode 113 is electrically conductively connected to at least two semiconductor components.

1-12. (canceled)

13. A vertical semiconductor component including transistor, comprising:
a drift layer and/or an active layer formed using gallium nitride (GaN); and
at least two electrodes including at least one measuring electrode, the measuring electrode being formed at a lower vertical level than at least one other of the electrodes and is configured to be contactable from vertically above.

14. The vertical semiconductor component according to claim 13, wherein the at least two electrodes includes three electrodes.

15. The vertical semiconductor component according to claim 13, wherein the measuring electrode is formed on a contact semiconductor layer.

16. The vertical semiconductor component according to claim 13, further comprising a foreign substrate which does not include gallium nitride.

17. The vertical semiconductor component according to claim 15, further comprising an intermediate layer configured to compensate for a lattice mismatch between a foreign substrate and the contact semiconductor layer and/or the drift layer.

18. The vertical semiconductor component according to claim 13, wherein the measuring electrode extends over a portion of a width and of a length of the semiconductor component and is arranged in an edge region of the semiconductor component.

19. The vertical semiconductor component according to claim 18, wherein the edge region is a corner region of the semiconductor component.

20. A composite of semiconductor components, comprising:
a plurality of vertical semiconductor components arranged next to one another in a longitudinal direction and/or in a width direction, each of the vertical semiconductor components including:
a drift layer and/or an active layer formed using gallium nitride (GaN), and
at least two electrodes including at least one measuring electrode, the measuring electrode being formed at a lower vertical level than at least one other of the electrodes and is configured to be contactable from vertically above
wherein the measuring electrode of each of the vertical semiconductor components is formed in a transition region of two of the vertical semiconductor components.

21. The composite of semiconductor components according to claim 20, wherein the transition region is a sawing region for separating the semiconductor components.

22. The composite of semiconductor components according to claim 20, wherein each of the measuring electrodes is formed circumferentially around the semiconductor component.

23. The composite of semiconductor components according to claim 20, wherein a single measuring electrode is electrically conductively connected to at least two semiconductor components.

24. A method for producing a vertical semiconductor component including a transistor, the vertical semiconductor component including at least two electrodes and a drift layer and/or active layer formed using gallium nitride, the method comprising the following method steps:
forming a semiconductor layer structure including at least the drift layer, the active layer, at least one electrode, and a vertically lower contact semiconductor layer on a foreign substrate;
ablating the semiconductor layer structure up to the contact semiconductor layer in a portion of a surface in which the semiconductor layer structure has been formed;
forming a vertically lower measuring electrode on the contact semiconductor layer exposed by the ablation.

25. The method according to claim 24, wherein after a testing or characterization method using the at least one electrode and the measuring electrode, a carrier material is fastened onto the semiconductor layer structure and covers the at least one electrode and/or makes it inaccessible.

26. The method according to claim 24, wherein the foreign substrate, together with an intermediate layer for compensating for a lattice mismatch between the foreign substrate and the contact semiconductor layer, is removed so that the contact semiconductor layer is exposed at least in sections.

27. The method according to claim 24, wherein a drain electrode is deposited on the contact semiconductor layer.
